(19) United States
(12) Patent Application Publication
(10) Pub. No.: US 2024/0268116 A1
(43) Pub. Date: Aug. 8, 2024

(54) Memory Circuitry And Method Used In Forming Memory Circuitry

(71) Applicant: Micron Technology, Inc., Boise, ID (US)

(72) Inventors: Amiya Banerjee, Bangalore (IN); Kranthi Kumar Vaidyula, Bangalore (IN); Davide Resnati, Vimercate (IT); Byeung Chul Kim, Boise, ID (US); Kyubong Jung, Boise, ID (US); Jameer Babasaheb Mulani, Bangalore (IN); Jae Kyu Choi, Boise, ID (US); Gianpietro Carnevale, Bottanuco (IT)

(73) Assignee: Micron Technology, Inc., Boise, ID (US)

(21) Appl. No.: 18/403,266

(22) Filed: Jan. 3, 2024

Related U.S. Application Data
(60) Provisional application No. 63/442,852, filed on Feb. 2, 2023.

(51) Int. Cl. H10B 43/27; H10B 43/35

(52) U.S. Cl. CPC H10B 43/27; H10B 43/35

(57) ABSTRACT

A method used in forming memory circuitry comprises forming a stack comprising vertically-alternating first tiers and second tiers. The first tiers are conductive and the second tiers are insulative at least in a finished-circuitry construction. Channel openings are formed through the first and second tiers. Charge-storage material is formed in the channel openings through the first and second tiers. The charge-storage material comprises a first charge-trap density. The first charge-trap density of the charge-storage material that is in the first tiers is increased as compared to the charge-storage material that is in the second tiers to a second charge-trap density. Channel material is formed in the channel openings through the first and second tiers and that is laterally-inward of the charge-storage material. Other embodiment, including structure, are disclosed.

### TECHNICAL FIELD

Embodiments disclosed herein pertain to circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

Memory arrays may be arranged in memory pages, memory blocks and partial blocks (e.g., sub-blocks), and memory planes, for example as shown and described in any of U.S. Patent Application Publication Nos. 2015/0228651, 2016/0267984, and 2017/0140833. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

### BRIEF DESCRIPTION OF THE DRAWINGS

FIGS. 1-4 are diagrammatic cross-sectional Views of portions of a construction that will comprise an array of elevationally-extending strings of memory cells in accordance with an embodiment of the invention.

FIGS. 5-20 are diagrammatic sequential sectional, expanded, enlarged, and/or partial Views of the construction of FIGS. 1-4, or portions thereof, and/or alternate embodiments in process in accordance with some embodiments of the invention.

### DETAILED DESCRIPTION OF EXAMPLE EMBODIMENTS

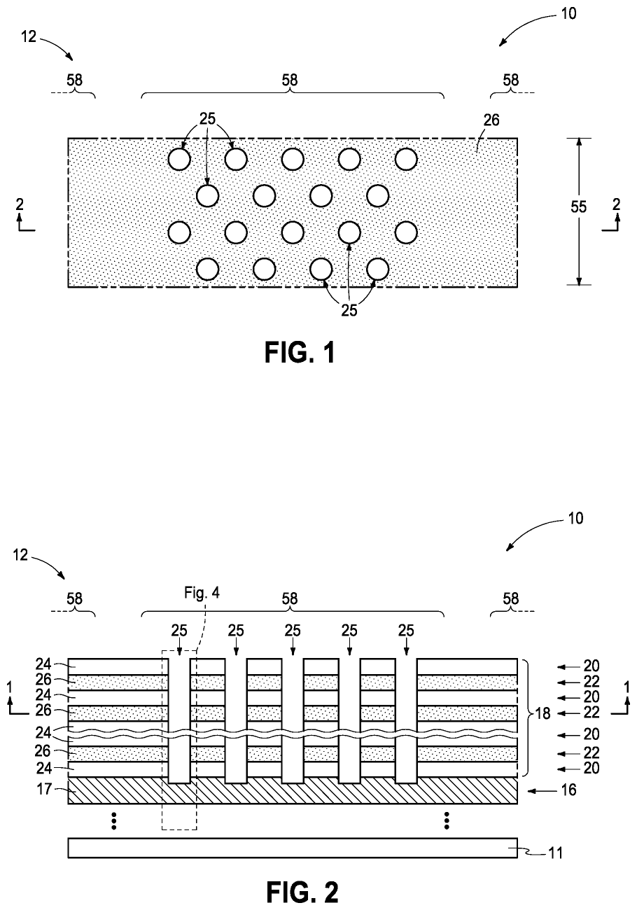

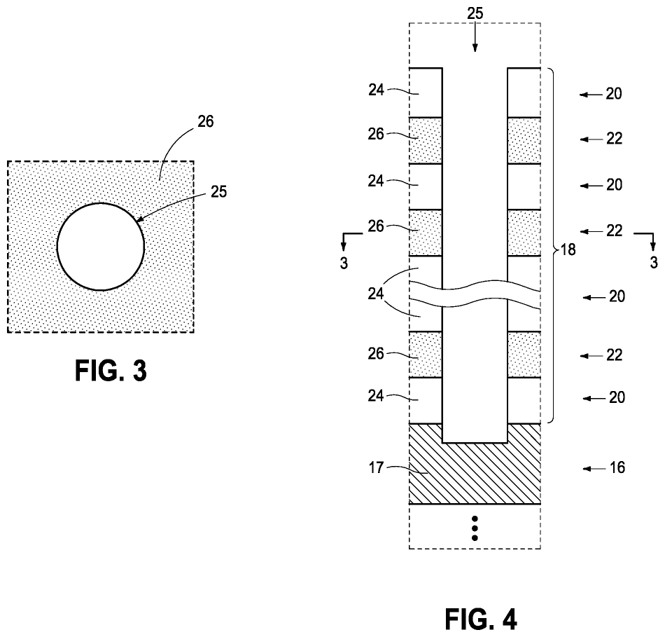

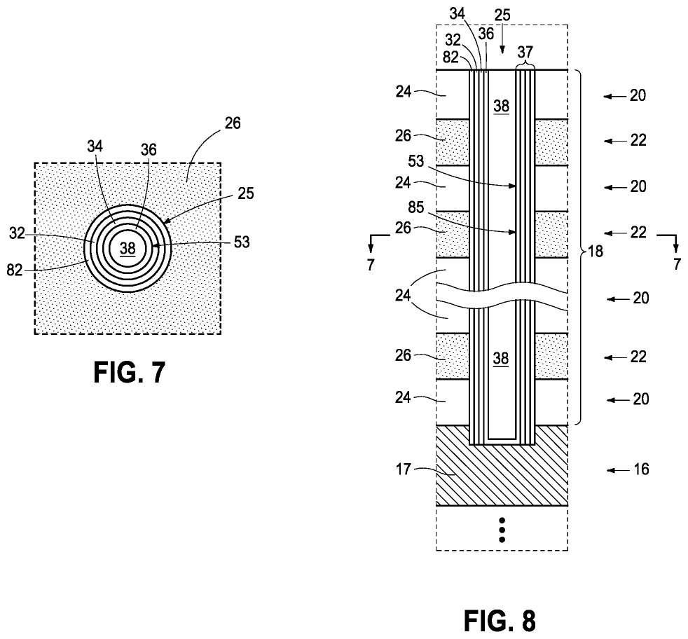

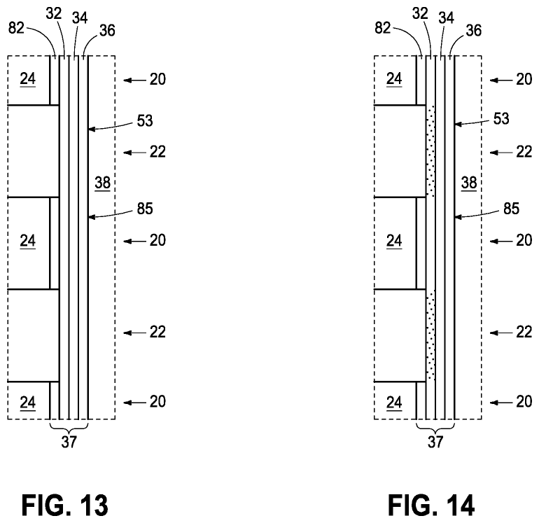

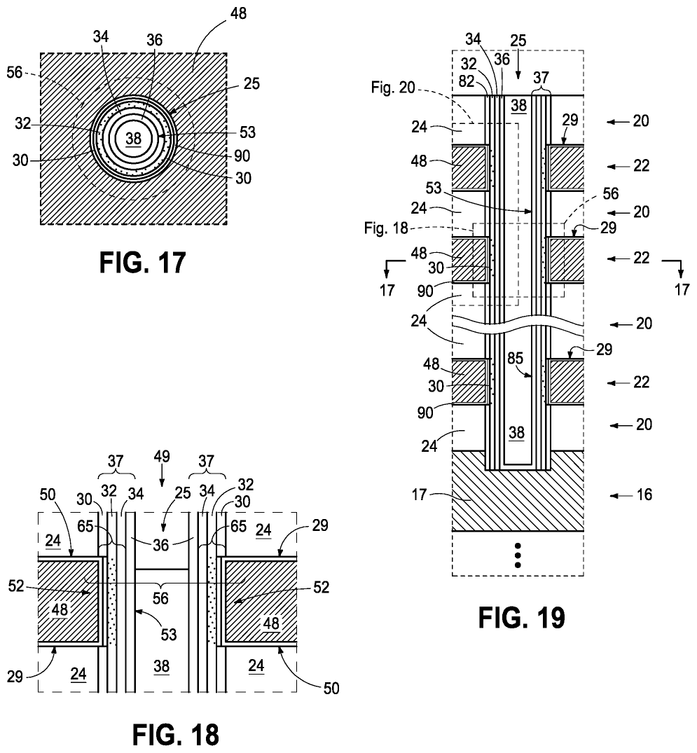

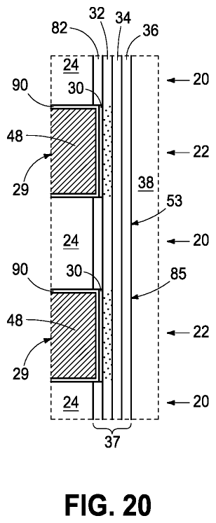

Embodiments of the invention encompass methods used in forming integrated circuitry, for example memory circuitry comprising a memory array, for example an array of NAND or other memory cells that may have at least some peripheral control circuitry under the array (e.g., CMOS-under-array). Embodiments of the invention also encompass integrated circuitry such as that comprising a memory array comprising strings of memory cells (e.g., NAND architecture) independent of method of manufacture. Some example embodiments are described with reference to FIGS. 1-20.

FIGS. 1-4 show an example construction 10 having an array 12 in which elevationally-extending strings of transistors and/or memory cells will be formed. Such includes a base substrate 11 having any one or more of conductive/conductor/conducting, semiconductive/semiconductor/semiconducting, or insulative/insulator/insulating (i.e., electrically herein) materials. Various materials have been formed elevationally over base substrate 11. Materials may be aside, elevationally inward, or elevationally outward of the FIGS. 1-4-depicted materials. For example, other partially or wholly fabricated components of integrated circuitry may be provided somewhere above, about, or within base substrate 11. Control and/or other peripheral circuitry for operating components within an array (e.g., array 12) of elevationally-extending strings of memory cells may also be fabricated and may or may not be wholly or partially within an array or sub-array. Further, multiple sub-arrays may also be fabricated and operated independently, in tandem, or otherwise relative one another. In this document, a “sub-array” may also be considered as an array.

A conductor tier 16 comprising conductor material 17 (e.g., WSiₓ under conductively-doped polysilicon) has been formed above substrate 11. Conductor tier 16 may comprise part of control circuitry (e.g., peripheral-under-array circuitry and/or a common source line or plate) used to control read and write access to the transistors and/or memory cells that will be formed within array 12.

A stack 18 comprising vertically-alternating first tiers 22 and second tiers 20 is directly above conductor tier 16, with first tiers 22 comprising sacrificial material 26 (e.g., silicon nitride) and second tiers 20 comprising non-sacrificial material 24 that is of different composition from that of sacrificial material 26 (e.g., silicon dioxide). In some embodiments, first tiers 22 may be referred to as conductive tiers 22 and second tiers 20 may be referred to as insulative tiers 20, with first tiers 22 being conductive and second tiers 20 being insulative at least in a finished-circuitry construction in some embodiments. Example thickness for each of tiers 20 and 22 is 20 to 60 nanometers. The example uppermost tier 20 may be thicker/thickest compared to one or more other tiers 20 and/or 22. Only a small number of tiers 20 and 22 is shown, with more likely stack 18 comprising dozens, a hundred or more, etc. of tiers 20 and 22. Other circuitry that may or may not be part of peripheral and/or control circuitry may be between conductor tier 16 and stack 18. For example, multiple vertically-alternating tiers of conductive material and insulative material of such circuitry may be below a lowest of the first tiers 22 and/or above an uppermost of the first tiers 22. For example, one or more select gate tiers (not shown) may be between conductor tier 16 and the lowest first tier 22 and one or more select gate tiers may be above an uppermost of first tiers 22 (not shown). Alternately or additionally, at least one of the depicted uppermost and lowest first tiers 22 may be a select gate tier.

Stack 18 comprises laterally-spaced memory-block regions 58 that will comprise laterally-spaced memory blocks 58 in a finished-circuitry construction. In this document, unless otherwise indicated, “block” is generic to include “sub-block”. Memory-block regions 58 and resultant memory blocks 58 (not yet shown) may be considered as being longitudinally elongated and oriented, for example along a direction 55.

Channel openings 25 have been formed (e.g., by etching) through first and second tiers 22 and 20 in memory-block regions 58. Channel openings 25 may taper radially-inward and/or radially-outward (not shown) moving deeper into stack 18. In some embodiments, channel openings 25 may go into conductor material 17 of conductor tier 16 as shown or may stop there-atop (not shown). A reason for extending channel openings 25 at least to conductor material 17 of conductor tier 16 is to provide an anchoring effect to material that is within channel openings 25. Example channel openings 25 are arranged in groups or columns of staggered rows of four and five per row in memory-block region 58. Alternate arrangements may of course be used.

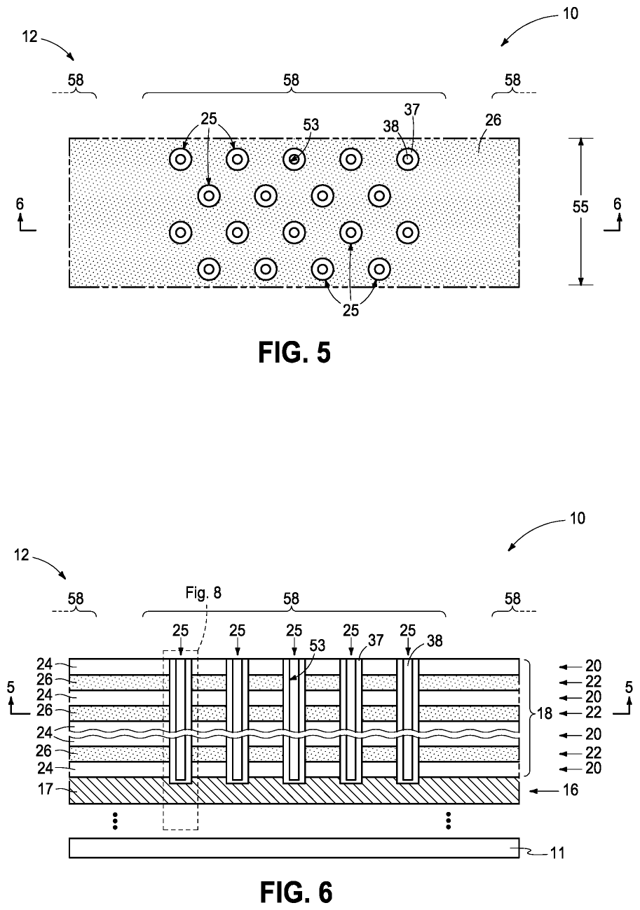

Referring to FIGS. 5-8, insulator material 82 has been formed in channel openings 25 through first and second tiers 22, 20, and is of different composition from that of sacrificial material 26 and from that of non-sacrificial material 24. Examples include so-called “high k” insulative metal oxides and other materials, for example insulative metal oxides having one or more than one metal element(s). Some specific examples of these and another are hafnium oxide, aluminum oxide, yttrium oxide, zirconium oxide, and SiCN, and in some such example embodiments where sacrificial material 26 comprises silicon nitride and non-sacrificial material 24 comprises silicon dioxide.

Transistor channel material may be formed in the individual channel openings elevationally along the first and second tiers, thus comprising individual channel-material strings, which is directly electrically coupled with conductor material in the conductor tier. Individual memory cells of the example memory array being formed may comprise a gate region (e.g., a control-gate region) and a memory structure laterally-between the gate region and the channel material. In one such embodiment, the memory structure is formed to comprise a charge-blocking region, storage material (e.g., charge-storage material), and an insulative charge-passage material. The storage material (e.g., floating gate material such as doped or undoped silicon or charge-trapping material such as silicon nitride, metal dots, etc.) of the individual memory cells is elevationally along individual of the charge-blocking regions. The insulative charge-passage material (e.g., a band gap-engineered structure having nitrogen-containing material [e.g., silicon nitride] sandwiched between two insulator oxides [e.g., silicon dioxide]) is laterally-between the channel material and the storage material.

Charge-storage material 32 has been formed in channel openings 25 through first and second tiers 22, 20, laterally-inward (e.g., radially-inward) of insulator material 82. Charge-storage material 32 comprises a first charge-trap density (i.e., that may be homogenously uniform throughout or that may be some average charge-trap density if not homogeneously uniform throughout; i.e.,“charge-trap density” being number of “charge traps” per unit volume, a “charge trap” being an energy site [a physical location] capable of trapping charge). Any suitable charge-storage material 32 may be used, with one ideal example being SiₓN_{y}O_{z}, where the x and the y are greater than 0, and where the z is 0 or greater than 0. As more specific examples, the x is 0.2 to 3.0, the y is 0.2 to 4.0, and the z is 0 to 2.0.

In one embodiment and as shown, charge-passage material 34 has been formed in individual channel openings 25 through first and second tiers 22, 20. Channel material 36 has then been formed in channel openings 25 through the first and second tiers 22, 20 laterally-inward (e.g., radially-inward) of charge-storage material 32 (e.g., and charge-passage material 34). Materials 82, 32, 34, and 36 are collectively shown as and only designated as material 37 in some figures due to scale. Channel-material 36 comprises individual channel-material strings 53 as part of individual channel-material-string constructions 85 (e.g., the latter comprising materials 32, 34, and 36 in combination). Example channel materials 36 include appropriately-doped crystalline semiconductor material, such as one or more silicon, germanium, and so-called III/V semiconductor materials (e.g., GaAs, InP, GaP, and GaN). Punch etching may be conducted to remove materials 82, 32, and 34 from the bases of channel openings 25 (as shown) to expose conductor tier 16 such that channel material 36 is directly against conductor material 17 of conductor tier 16 (as shown). Such punch etching may occur separately with respect to each of materials 32 and 34 (as shown) or may occur with respect to only some (not shown). Alternately, and by way of example only, no punch etching may be conducted and channel material 36 may be directly electrically coupled to conductor material 17 of conductor tier 16 only by a separate conductive interconnect (not shown). Regardless, sacrificial etch-stop plugs (not shown) may be formed in or above conductor tier 16 in horizontal locations where channel openings 25 will be prior to forming stack 18. Channel openings 25 may then be formed by etching materials 24 and 26 to stop on or within the material of the sacrificial plugs, followed by exhuming remaining material of such plugs prior to forming material in channel openings 25. A radially-central solid dielectric material 38 (e.g., spin-on-dielectric, silicon dioxide, and/or silicon nitride) is shown in channel openings 25. Alternately, and by way of example only, the radially-central portion within channel openings 25 may include void space(s) (not shown) and/or be devoid of solid material (not shown).

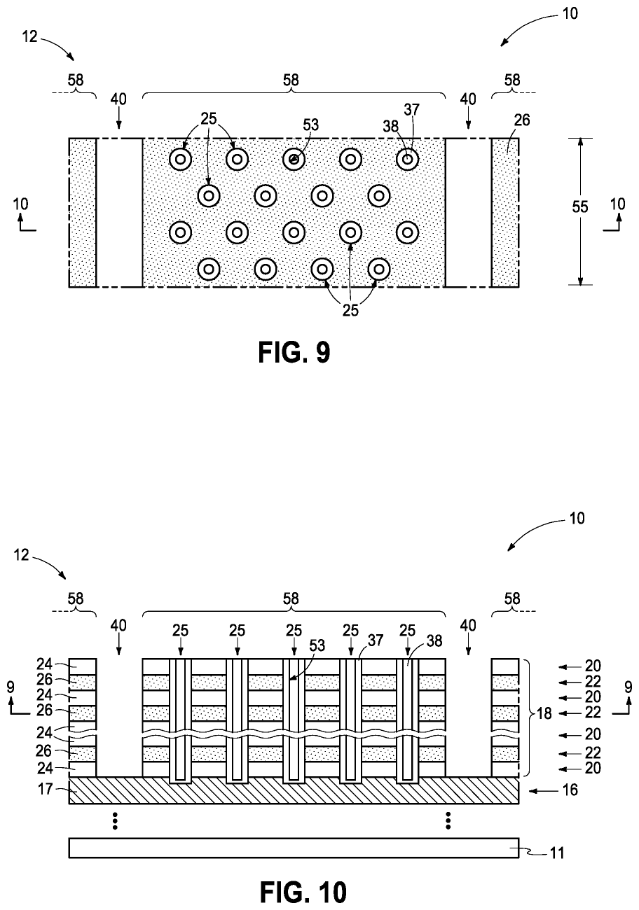

Referring to FIGS. 9 and 10, horizontally-elongated trenches 40 have been formed (e.g., by anisotropic etching) between immediately-laterally-adjacent memory-block regions 58. Trenches 40 will typically be wider than channel openings 25 (e.g., 3 to 10 times wider). Trenches 40 may have respective bottoms that are directly against conductor material 17 (e.g., atop or within) of conductor tier 16 (as shown) or may have respective bottoms that are above conductor material 17 of conductor tier 16 (not shown). Trenches 40 may taper laterally inward and/or outward in vertical cross-section (not shown).

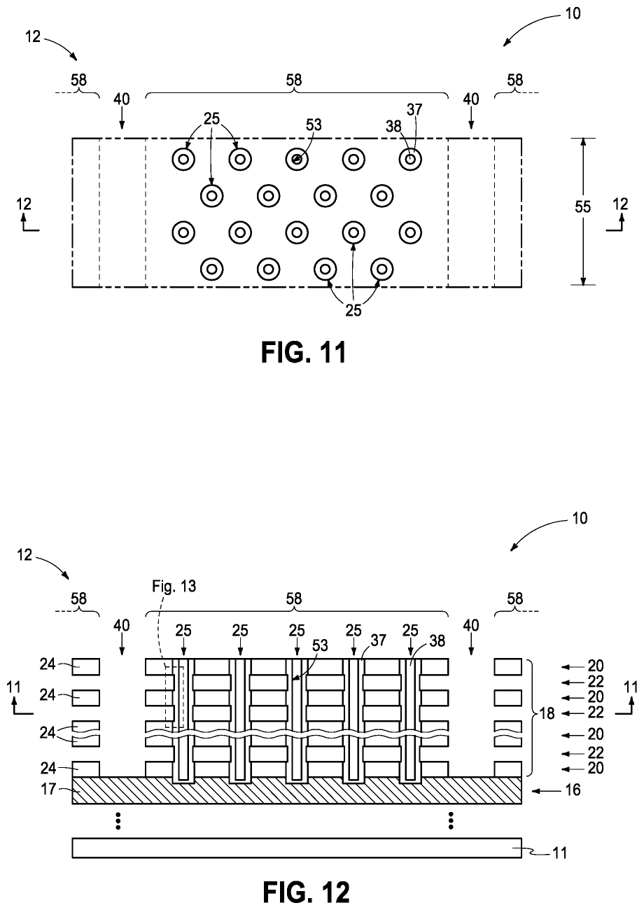

Referring to FIGS. 11-13, sacrificial material 26 (not shown) and insulator material 82 have been removed (e.g., by etching used a different etching chemistry for each) from first tiers 22 to expose charge-storage material 32 in first tiers 22. The artisan is capable of selecting suitable anisotropic and/or isotropic etching chemistries to achieve the example-depicted construction depending on compositions of materials 26, 82, 24, and 32.

Referring to FIG. 14, the first charge-trap density of exposed charge-storage material 32 that is in first tiers 22 has been increased as compared to charge-storage material 32 that is in second tiers 20 to a second charge-trap density. Such second charge-trap density in charge-storage material 32 is diagrammatically indicated with stippling, with the first charge-trap density in charge-storage material 32 being indicated by a lack of stippling. In one embodiment, the second charge-trap density is at least twice the first charge-trap density, in one such embodiment at least five times the first charge-trap density, and in one such embodiment is at least ten times the first charge-trap density. In one embodiment where charge-storage material 32 comprises SiₓN_{y}O_{z}, the charge-storage material where having the second charge-trap density has more nitrogen than the charge-storage material having the second charge-trap density. In one such embodiment, the increasing comprises adding nitrogen to the charge-storage material, and in one embodiment comprises removing at least one of silicon and oxygen from the charge-storage material. In one such latter embodiment, the increasing comprises removing silicon and in one such embodiment the z is greater than zero and the increasing comprises removing oxygen. The artisan is capable of selecting suitable processing that will increase the charge-trap density of an as-deposited charge-storage material 32 depending on its composition. For example, and by way of example only, silicon nitride and SiₓN_{y}O_{z} can have their respective charge-trap densities increased by exposure to a nitrogen-containing plasma (e.g., derived from N₂ and/or NH₃) or by exposure to NH₃ in the absence of plasma (both of which increase nitrogen concentration and thereby charge-trap density as compared to the as-deposited material).

In one embodiment and as shown, channel material 36 has been formed after forming charge-storage material 32 and in one such embodiment before increasing the first charge-trap density to the second charge-trap density.

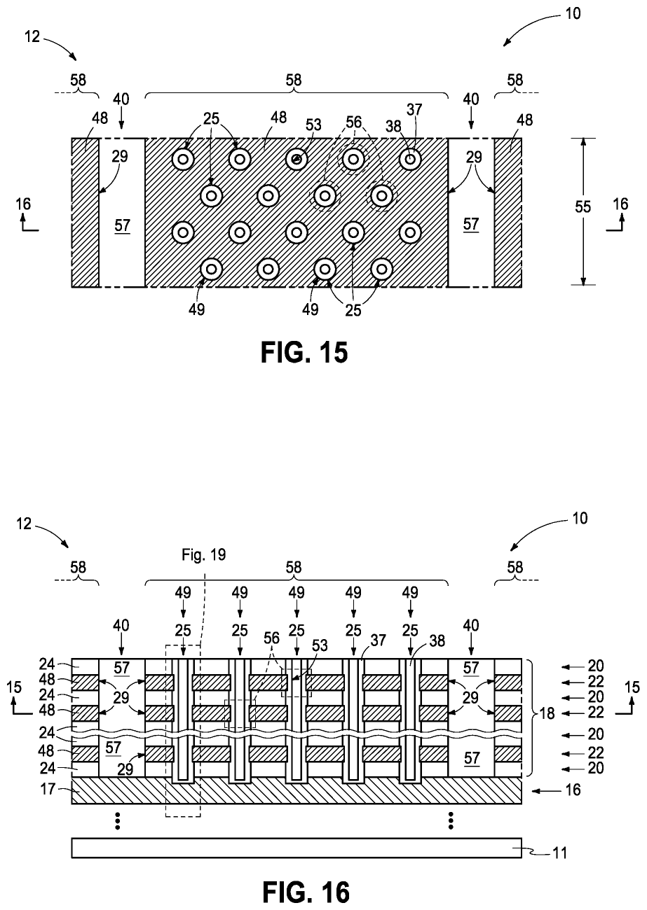

Referring to FIGS. 15-20, through horizontally-elongated trenches 40, conducting material 48 has been formed in first tiers 22, and which has thereafter been removed from trenches 40, thus forming individual control-gate lines 29 (e.g., wordlines) in memory-block regions 58 and elevationally-extending strings 49 of individual transistors and/or memory cells 56 in stack 18. A thin insulative liner 90 (e.g., Al₂O₃ or other high-k material) may be formed before forming conducting material 48. Alternately, or in addition thereto, charge-storage material 32 in first tiers 22 may be partially oxidized to form charge-blocking material 30 (e.g., SiO₂). Approximate locations of transistors and/or memory cells 56 are indicated with a bracket in some figures and some with dashed outlines in some figures, with transistors and/or memory cells 56 being essentially ring-like or annular in the depicted example. Alternately, transistors and/or memory cells 56 may not be completely encircling relative to individual channel openings 25 such that each channel opening 25 may have two or more elevationally-extending strings 49 (e.g., multiple transistors and/or memory cells about individual channel openings in individual conductive tiers with perhaps multiple wordlines per channel opening in individual conductive tiers, and not shown). Conducting material 48 may be considered as having terminal ends 50 corresponding to control-gate regions 52 of individual transistors and/or memory cells 56. Control-gate regions 52 in the depicted embodiment comprise individual portions of individual conductive lines 29. Materials 30, 32, and 34 may be considered as a memory structure 65 that is laterally between control-gate region 52 and channel material 36.

A charge-blocking region (e.g., charge-blocking material 30 and/or liner 90) is between storage material 32 and individual control-gate regions 52. A charge block may have the following functions in a memory cell: In a program mode, the charge block may prevent charge carriers from passing out of the storage material (e.g., floating-gate material, charge-trapping material, etc.) toward the control gate, and in an erase mode the charge block may prevent charge carriers from flowing into the storage material from the control gate. Accordingly, a charge block may function to block charge migration between the control-gate region and the storage material of individual memory cells. An example charge-blocking region as shown comprises insulator material 30 and insulative liner 90. By way of further examples, a charge-blocking region may comprise a laterally (e.g., radially) outer portion of the storage material (e.g., material 32) where such storage material is insulative (e.g., in the absence of any different-composition material between an insulative storage material 32 and conducting material 48). Regardless, as an additional example, an interface of a storage material and conductive material of a control gate may be sufficient to function as a charge-blocking region in the absence of any separate-composition-insulator material 30 and/or 90. Further, an interface of conducting material 48 with material 30 (when present) in combination with insulator material 30 and/or may together function as a charge-blocking region, and as alternately or additionally may a laterally-outer region of an insulative storage material (e.g., a silicon nitride material 32). An example material 30 is one or more of silicon hafnium oxide and silicon dioxide.

Conducting material 48 is removed from trenches 40 and there-after trenches 40 are filled with intervening material 57. Intervening material 57 may provide lateral electrical isolation (insulation) between immediately-laterally-adjacent memory blocks 58. Such may include one or more of insulative, semiconductive, and conducting materials and, regardless, may facilitate conductive tiers 22 from shorting relative one another in a finished-circuitry construction. Example insulative materials are one or more of SiO₂, Si₃N₄, and Al₂O₃. Intervening material 57 in memory-array region 12 may include through-array vias (not shown).

Any other attribute(s) or aspect(s) as shown and/or described herein with respect to other embodiments may be used in the embodiments shown and described with reference to the above embodiments.

In one embodiment, a method used in forming memory circuitry (e.g., 10) comprises forming a stack (e.g., 18) comprising vertically-alternating first tiers (e.g., 22) and second tiers (e.g., 20). The first tiers are conductive and the second tiers are insulative at least in a finished-circuitry construction. Channel openings are formed through the first and second tiers. Charge-storage material (e.g., 32) is formed in the channel openings through the first and second tiers, with the charge-storage material comprising a first charge-trap density. The first charge-trap density of the charge-storage material that is in the first tiers is increased as compared to the charge-storage material that is in the second tiers to a second charge-trap density. Channel material (e.g., 36) is formed in the channel openings through the first and second tiers and is laterally-inward of the charge-storage material. Any other attribute(s) or aspect(s) as shown and/or described herein with respect to other embodiments may be used.

Aspects of the invention may, although are not required to, improve charge migration (reduce or eliminate it) between immediately-adjacent memory cells in NAND or other memory circuitry.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, memory circuitry (e.g., 10) comprising strings (e.g., 49) of memory cells (e.g., 56) comprises a stack (e.g., 18) comprising vertically-alternating insulative tiers (e.g., 20) and conductive tiers (e.g., 22). Strings (e.g., 49) of memory cells (e.g., 56) comprise channel-material-string constructions (e.g., 85) that extend through the insulative tiers and the conductive tiers. The channel-material-string constructions individually comprise a channel-material string (e.g., 53) that extends through the insulative tiers and the conductive tiers. Further, such channel-material-string construction comprises a charge-storage-material string (e.g., charge-storage material 32) that extends through the insulative tiers and the conductive tiers laterally-outward of the channel-material string. The charge-storage-material string comprises a first charge-trap density in the insulative tiers and a second charge-trap density in the conductive tiers, with the first charge-trap density being less than the second charge-trap density. A control-gate line (e.g., 29) is in individual of the conductive tiers laterally-outward of the charge-storage material of individual of the charge-storage-material strings. Any other attribute(s) or aspect(s) as shown and/or described herein with respect to other embodiments may be used.

In one embodiment, memory circuitry (e.g., 12) comprising strings (e.g., 49) of memory cells (e.g., 56) comprises a stack (e.g., 18) comprising vertically-alternating insulative tiers (e.g., 20) and conductive tiers (e.g., 22). Strings (e.g., 49) of memory cells (e.g., 56) comprising channel-material-string constructions (e.g., 85) extend through the insulative tiers and the conductive tiers. The channel-material-string constructions individually comprise a channel-material string (e.g., 53) that extends through the insulative tiers and the conductive tiers. Such channel-material-string constructions individually comprise a storage-material string (e.g., storage material 32) that extends through the insulative tiers and the conductive tiers laterally-outward of the channel-material string. A control-gate line (e.g., 29) is in individual of the conductive tiers laterally-outward of the storage material of individual of the storage-material strings. The insulative tiers comprise different composition first and second insulator materials (e.g., 82, 24, respectively). The second insulator material is laterally-outward of and directly against the first insulator material and does not extend upwardly and downwardly into immediately-vertically-adjacent of the conductive tiers (i.e., there being no other conductive tier between conductive tiers that are immediately-vertically-adjacent one another). The first insulator material is laterally-outward of and directly against the storage material of individual of the storage-material strings and does not extend upwardly and downwardly into the immediately-vertically-adjacent conductive tiers. Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 450 from exactly horizontal. Further, “extend(ing) elevationally”, “elevationally-extending”, “extend(ing) horizontally”, “horizontally-extending” and the like with respect to a field effect transistor are with reference to orientation of the transistor-s channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 100 of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, on “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming a stack comprising vertically-alternating first tiers and second tiers. The first tiers are conductive and the second tiers are insulative at least in a finished-circuitry construction. Channel openings are formed through the first and second tiers. Charge-storage material is formed in the channel openings through the first and second tiers. The charge-storage material comprises a first charge-trap density. The first charge-trap density of the charge-storage material that is in the first tiers is increased as compared to the charge-storage material that is in the second tiers to a second charge-trap density. Channel material is formed in the channel openings through the first and second tiers and that is laterally-inward of the charge-storage material.

In some embodiments, a method used in forming memory circuitry comprises forming a stack comprising vertically-alternating first tiers and second tiers. The first tiers comprise sacrificial material and the second tiers comprise non-sacrificial material that is of different composition from that of the sacrificial material. The stack comprises memory-block regions. Channel openings are formed through the first and second tiers in the memory-block regions. Insulator material is formed in the channel openings through the first and second tiers. The insulator material is of different composition from that of the sacrificial material and from that of the non-sacrificial material. Charge-storage material is formed in the channel openings through the first and second tiers laterally-inward of the insulator material. The charge-storage material comprises a first charge-trap density. Channel material is formed in the channel openings through the first and second tiers laterally-inward of the charge-storage material. Through horizontally-elongated trenches that individually extend through the first tiers and the second tiers between immediately-adjacent of the memory-block regions, the sacrificial material and the insulator material are removed from the first tiers to expose the charge-storage material in the first tiers. The first charge-trap density of the exposed charge-storage material that is in the first tiers is increased as compared to the charge-storage material that is in the second tiers to a second charge-trap density. Through the horizontally-elongated trenches, conducting material is formed in the first tiers and that comprises control-gate lines in the memory-block regions.

In some embodiments, memory circuitry comprising strings of memory cells comprises a stack comprising vertically-alternating insulative tiers and conductive tiers. Strings of memory cells comprise channel-material-string constructions that extend through the insulative tiers and the conductive tiers. The channel-material-string constructions individually comprise a channel-material string that extends through the insulative tiers and the conductive tiers. A charge-storage-material string extends through the insulative tiers and the conductive tiers laterally-outward of the channel-material string. The charge-storage-material string comprises a first charge-trap density in the insulative tiers and a second charge-trap density in the conductive tiers. The first charge-trap density is less than the second charge-trap density. A control-gate line is in individual of the conductive tiers laterally-outward of the charge-storage material of individual of the charge-storage-material strings.

In some embodiments, memory circuitry comprising strings of memory cells comprises a stack comprising vertically-alternating insulative tiers and conductive tiers. Strings of memory cells comprise channel-material-string constructions that extend through the insulative tiers and the conductive tiers. The channel-material-string constructions individually comprise a channel-material string that extends through the insulative tiers and the conductive tiers. A storage-material string extends through the insulative tiers and the conductive tiers laterally-outward of the channel-material string. A control-gate line is in individual of the conductive tiers laterally-outward of the storage material of individual of the storage-material strings. The insulative tiers comprise different composition first and second insulator materials. The second insulator material is laterally-outward of and directly against the first insulator material and does not extend upwardly and downwardly into immediately-vertically-adjacent of the conductive tiers. The first insulator material is laterally-outward of and directly against the storage material of individual of the storage-material strings and does not extend upwardly and downwardly into the immediately-vertically-adjacent conductive tiers.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming a stack comprising vertically-alternating first tiers and second tiers, the first tiers being conductive and the second tiers being insulative at least in a finished-circuitry construction;
forming channel openings through the first and second tiers;
forming charge-storage material in the channel openings through the first and second tiers, the charge-storage material comprising a first charge-trap density;
increasing the first charge-trap density of the charge-storage material that is in the first tiers as compared to the charge-storage material that is in the second tiers to a second charge-trap density; and
forming channel material in the channel openings through the first and second tiers and that is laterally-inward of the charge-storage material.

2. The method of claim 1 comprising forming the channel material after forming the charge-storage material.

3. The method of claim 2 comprising forming the channel material before the increasing.

4. The method of claim 1 wherein the second charge-trap density is at least twice the first charge-trap density.

5. The method of claim 4 wherein the second charge-trap density is at least five times the first charge-trap density.

6. The method of claim 5 wherein the second charge-trap density is at least ten times the first charge-trap density.

7. The method of claim 1 wherein the charge-storage material comprises SiₓN_{y}O_{z}, where the x and the y are greater than 0, and where the z is 0 or greater than 0.

8. The method of claim 7 wherein the x is 0.2 to 3.0, the y is 0.2 to 4.0, and the z is 0 to 2.0.

9. The method of claim 7 wherein the charge-storage material having the second charge-trap density has more nitrogen than the charge-storage material having the second charge-trap density.

10. The method of claim 9 wherein the increasing comprises adding nitrogen to the charge-storage material.

11. The method of claim 9 wherein the increasing comprises removing at least one of silicon and oxygen from the charge-storage material.

12. The method of claim 11 wherein the increasing comprises removing silicon.

13. The method of claim 11 wherein the z is greater than zero and the increasing comprises removing oxygen.

14. Memory circuitry comprising strings of memory cells, comprising:
a stack comprising vertically-alternating insulative tiers and conductive tiers;
strings of memory cells comprising channel-material-string constructions that extend through the insulative tiers and the conductive tiers, the channel-material-string constructions individually comprising:
a channel-material string that extends through the insulative tiers and the conductive tiers; and
a charge-storage-material string that extends through the insulative tiers and the conductive tiers laterally-outward of the channel-material string, the charge-storage-material string comprising a first charge-trap density in the insulative tiers and a second charge-trap density in the conductive tiers, the first charge-trap density being less than the second charge-trap density; and
a control-gate line in individual of the conductive tiers laterally-outward of the charge-storage material of individual of the charge-storage-material strings.

15. The memory circuitry of claim 14 wherein the second charge-trap density is at least twice the first charge-trap density.

16. The memory circuitry of claim 15 wherein the second charge-trap density is at least five times the first charge-trap density.

17. The memory circuitry of claim 16 wherein the second charge-trap density is at least ten times the first charge-trap density.

18. The memory circuitry of claim 14 wherein the charge-storage material comprises SiₓN_{y}O_{z}, where the x and the y are greater than 0, and where the z is 0 or greater than 0.

19. The memory circuitry of claim 18 wherein the x is 0.2 to 3.0, the y is 0.2 to 4.0, and the z is 0 to 2.0.

20. Memory circuitry comprising strings of memory cells, comprising:
a stack comprising vertically-alternating insulative tiers and conductive tiers;
strings of memory cells comprising channel-material-string constructions that extend through the insulative tiers and the conductive tiers, the channel-material-string constructions individually comprising:
a channel-material string that extends through the insulative tiers and the conductive tiers; and
a storage-material string that extends through the insulative tiers and the conductive tiers laterally-outward of the channel-material string;
a control-gate line in individual of the conductive tiers laterally-outward of the storage material of individual of the storage-material strings; and
the insulative tiers comprising different composition first and second insulator materials, the second insulator material being laterally-outward of and directly against the first insulator material and not extending upwardly and downwardly into immediately-vertically-adjacent of the conductive tiers, the first insulator material being laterally-outward of and directly against the storage material of individual of the storage-material strings and not extending upwardly and downwardly into the immediately-vertically-adjacent conductive tiers.
